(19) United States
(12) Patent Application Publication
(10) Pub. No.: US 2023/0402095 A1
(43) Pub. Date: Dec. 14, 2023

(54) SEMICONDUCTOR MEMORY DEVICE INCLUDING CHALCOGENIDE

(71) Applicant: SK Hynix Inc., Icheon (KR)

(72) Inventors: Jong Ho LEE, Icheon (KR); Jun Ku Ahn, Icheon (KR); Gwang Sun Jung, Icheon (KR); Uk Hwang, Icheon (KR)

(21) Appl. No.: 18/060,884

(22) Filed: Dec. 1, 2022

(30) Foreign Application Priority Data
Jun. 14, 2022 (KR) 10-2022-0072250

(51) Int. Cl. G11C 13/00; H10B 63/00; H10N 70/00

(52) U.S. Cl. CPC G11C 13/0069; H01L 45/1253; H01L 45/144; H01L 27/2481

(57) ABSTRACT

A semiconductor memory device includes a memory cell interposed between a first electrode and a second electrode, and configured with a chalcogenide layer that includes three or more components, and a peripheral circuit for providing the memory cell with a program pulse inducing a compositional gradient in the chalcogenide layer.

### CROSS-REFERENCE TO RELATED APPLICATION

The present application claims priority under 35 U.S.C. § 119(a) to Korean patent application number 10-2022-0072250, filed on Jun. 14, 2022, in the Korean Intellectual Property Office, the entire disclosure of which is incorporated herein by reference.

### BACKGROUND

### 1. Technical Field

The present disclosure generally relates to an electronic device, and more particularly, to a semiconductor memory device including a chalcogenide.

### 2. Related Art

An electronic device includes a semiconductor memory device for storing data. The semiconductor memory device includes a memory cell capable of storing, as data, two or more logical states. As miniaturization and high performance of electronic devices are required, various techniques for improving a degree of integration of memory cells included in a semiconductor memory device and an operation speed in low power have been developed.

As semiconductor memory devices capable of improving the degree of integration and the operation speed in low power, next-generation memory devices have been proposed. The next-generation memory devices may include a Phase changeable random access memory (PRAM), a Magnetic random access memory (MRAM), a Resistance changeable random access memory (RRAM), and so on. Recently, development of next-generation memory devices advantageous in the degree of integration has been actively conducted.

### SUMMARY

In accordance with an aspect of the present disclosure, there is provided a semiconductor memory device including: a memory cell interposed between a first electrode and a second electrode, and configured with a chalcogenide layer that includes three or more components; and a peripheral circuit configured to provide a program pulse to the memory cell, wherein the program pulse induces a compositional gradient in the chalcogenide layer such that a content of at least one component of the chalcogenide layer has a difference of 5 at % or more between a first area and a second area in the chalcogenide layer, the first area being adjacent to the first electrode, and the second area being adjacent to the second electrode.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or one or more intervening elements may also be present. Like reference numerals refer to like elements throughout.

FIG. 1 is a diagram illustrating a semiconductor memory device in accordance with an embodiment of the present disclosure.

FIGS. 2A, 2B, and 2C are views exemplarily illustrating memory cell arrays of a semiconductor memory device in accordance with embodiments of the present disclosure.

FIGS. 3A and 3B are views illustrating a compositional gradient of a chalcogenide layer in accordance with an embodiment of the present disclosure.

FIG. 4 is a graph illustrating a current-voltage characteristic according to a program state of a memory cell in accordance with an embodiment of the present disclosure.

FIG. 5 is a phase equilibrium diagram illustrating a composition ratio of a chalcogenide layer of a memory cell in accordance with an embodiment of the present disclosure.

### DETAILED DESCRIPTION

The specific structural or functional description disclosed herein is merely illustrative for the purpose of describing embodiments according to the concept of the present disclosure. Embodiments according to the concept of the present disclosure may be implemented in various forms, and should not be construed as limited to the specific embodiments set forth herein.

Hereinafter, the terms such as “first” and “second” may be used to describe various components. However, the components should not be limited by these terms. These terms are used for distinguishing one element from another element and not to suggest a number or order of elements.

Embodiments provide a semiconductor memory device capable of improving operation reliability.

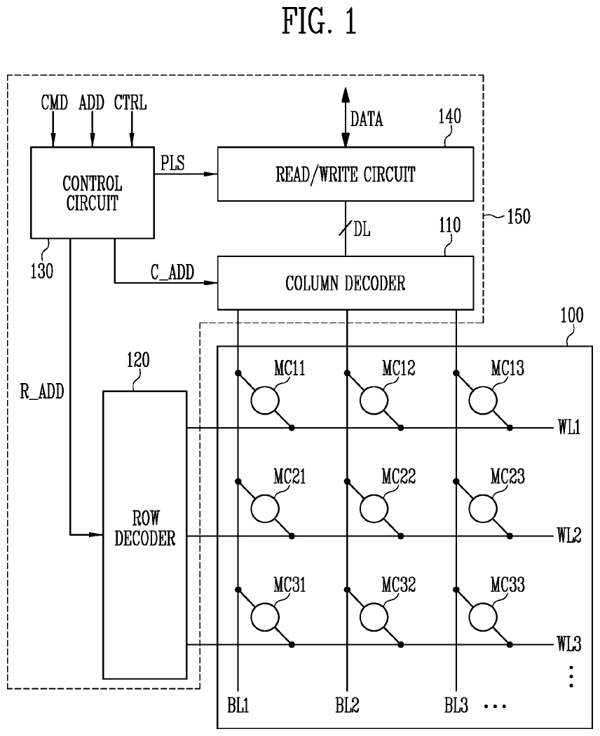

FIG. 1 illustrates a semiconductor memory device in accordance with an embodiment of the present disclosure.

Referring to FIG. 1, the semiconductor memory device may include a memory cell array 100 and a peripheral circuit 150. The peripheral circuit 150 may include a column decoder 110, a row decoder 120, a control circuit 130, and a read/write circuit 140 to control various operations of the memory cell array 100.

The memory cell array 100 may be connected to a plurality of first signal lines and a plurality of second signal lines. The memory cell array 100 may include a plurality of memory cells, e.g., MC11 to MC33, disposed in areas in which a plurality of word lines, e.g., WL1 to WL3, and a plurality of bit lines, e.g., BL1 to BL3, intersect each other.

Each of the memory cells MC11 to MC33 may include a chalcogenide layer having three or more components. Each of the memory cells MC11 to MC33 may have a threshold voltage corresponding to a program state. In an embodiment, the program state may be one of a set state having a first threshold voltage and a reset state having a second threshold voltage higher than the first threshold voltage.

The chalcogenide layer included in each of the memory cells MC11 to MC33 may be in an amorphous state when each of the memory cells MC11 to MC33 is in the set state and the reset state. The chalcogenide layer may have a compositional gradient corresponding to a threshold voltage. The compositional gradient may be defined when at least one of components constituting the chalcogenide layer is distributed to have different contents in the chalcogenide layer in an electric field direction. The compositional gradient may vary according to a program pulse applied to each of the memory cells MC11 to MC33.

For example, when a first memory cell MC11 is programmed with a first program pulse having a first polarity, at least one component, e.g., a first component, among the components included in the chalcogenide layer of the first memory cell MC11 may be distributed at different contents in the chalcogenide layer in the electric field direction, to thereby form a first compositional gradient in the chalcogenide layer. The first compositional gradient may correspond to the set state having the first threshold voltage.

When the first memory cell MC11 is programmed with a second program pulse having a second polarity different from the first polarity, the first component of the chalcogenide layer may be distributed at different contents in the chalcogenide layer in the electric field direction, to thereby form a second compositional gradient in the chalcogenide layer. The second compositional gradient may be different from the first compositional gradient. The second compositional gradient may correspond to the reset state having the second threshold voltage.

A read operation for reading data stored in the memory cells MC11 to MC33 may be performed to identify the data stored in the memory cells MC11 to MC33 by detecting a polarity of the program pulse using a polarity of a read pulse. In an embodiment, when the polarity of the program pulse and the polarity of the read pulse are the same, the first threshold voltage may be detected. When the polarity of the program pulse and the polarity of the read pulse are opposite to each other, the second threshold voltage different from the first threshold voltage may be detected. The first threshold voltage may correspond to the threshold voltage of the set state, and the second threshold voltage may correspond to the threshold voltage of the reset state. Therefore, the polarity of the program pulse may be determined based on the threshold voltage detected in the reading operation, and the data stored in the memory cells MC11 to MC33 may be identified by the polarity of the program pulse.

Each of the polarity of the program pulse and the polarity of the read pulse may be determined by a potential difference between a selected bit line and a selected word line. For example, the first polarity may be a positive polarity, and the second polarity may be a negative polarity. The positive polarity may be defined as a polarity when a voltage applied to the selected bit line is higher than a voltage applied to the selected word line. The negative polarity may be defined as a polarity when the voltage applied to the selected bit line is lower than the voltage applied to the selected word line.

The memory cell array 100 may be connected to the column decoder 110 through the bit lines BL1 to BL3. The column decoder 110 may select at least one of the bit lines BL1 to BL3 in response to a column address C_ADD. The column decoder 110 may transfer operating voltages for program and read operations to the bit lines BL1 to BL3.

The memory cell array 100 may be connected to the row decoder 120 through the word lines WL1 to WL3. The row decoder 120 may select at least one of the word lines WL1 to WL3 in response to a row address R_ADD. The row decoder 120 may transfer operating voltages for program and read operations to the word lines WL1 to WL3.

The control circuit 130 may receive a control signal CTRL and a command CMD, and operate according to the control signal CTRL and the command CMD. The control circuit 130 may provide a pulse control signal PLS to the read/write circuit 140 in response to the control signal CTRL and the command CMD.

The control circuit 130 may receive an address ADD. Based on the address ADD, the control circuit 130 may provide the row address R_ADD to the row decoder 120 and the column address C_ADD to the column decoder 110.

The pulse control signal PLS and data DATA may be input to the read/write circuit 140. The read/write circuit 140 may provide a program pulse, a read pulse, and the like to the column decoder 110 through data lines DL. The program pulse and the read pulse may have various forms for operations of the memory cell array 100. In an embodiment, each of the program pulse and the read pulse may have various forms by changing a level of current or a level of voltage. In an embodiment, widths of the program pulse and the read pulse may have various forms.

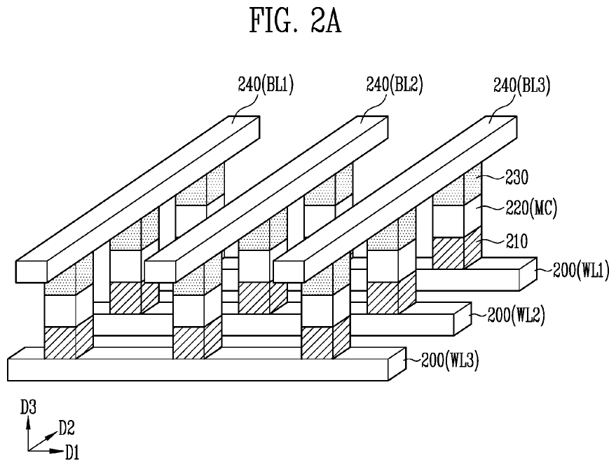

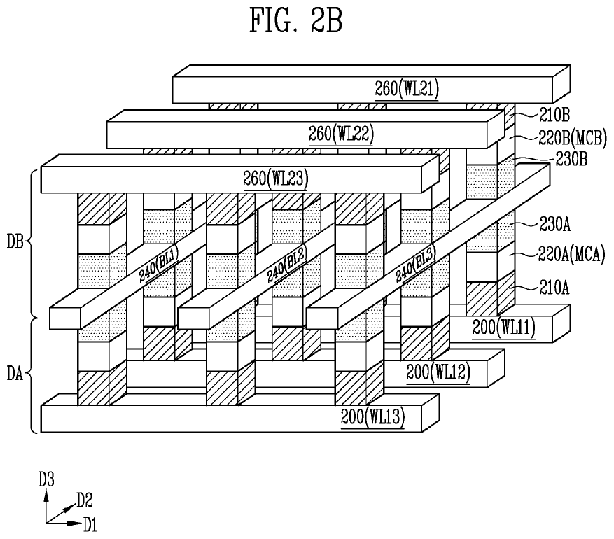

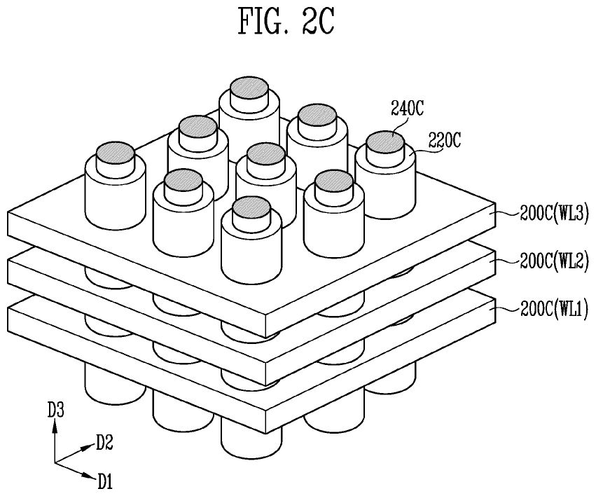

FIGS. 2A, 2B, and 2C illustrate memory cell arrays of a semiconductor memory device in accordance with embodiments of the present disclosure.

In the drawings, a first direction D1, a second direction D2, and a third direction D3 may be perpendicular to each other.

In an embodiment, the first direction D1, the second direction D2, and the third direction D3 may respectively correspond to an X axis, a Y axis, and a Z axis of an XYZ coordinate system.

Referring to FIG. 2A, a memory cell array may be configured as a single deck including a plurality of first conductive patterns 200, a plurality of second conductive patterns 240, and a plurality of memory cells MC.

The plurality of first conductive patterns 200 may extend in the first direction D1, and be used as a plurality of word lines WL1 to WL3. The plurality of second conductive patterns 240 may be arranged above the plurality of first conductive patterns 200, and extend in the second direction D2. The plurality of second conductive patterns 240 may be used as a plurality of bit lines BL1 to BL3.

Each of the memory cells MC may be disposed in an area in which a first conductive pattern 200 and a second conductive pattern 240 intersect each other, and be disposed between the first conductive pattern 200 and the second conductive pattern 240 in the third direction D3. The memory cell MC may be configured with a chalcogenide layer 220.

The memory cell array may further include a lower electrode 210 disposed between the chalcogenide layer 220 and the first conductive pattern 200, and an upper electrode 230 disposed between the chalcogenide layer 220 and the second conductive pattern 240. A voltage applied to the first conductive pattern 200 may be applied to the chalcogenide layer 220 through the lower electrode 210. A voltage applied to the second conductive pattern 240 may be applied to the chalcogenide layer 220 through the upper electrode 230.

Two or more memory cells MC disposed in a line in the first direction D1 may be connected in parallel to each of the first conductive patterns 200. Two or more memory cells MC disposed in a line in the second direction D2 may be connected in parallel to each of the second conductive patterns 240.

Referring to FIG. 2B, a memory cell array may be formed in a multi-deck structure in which two or more decks are stacked in the third direction D3. In an embodiment, the memory cell array may include a first deck DA and a second deck DB disposed on the first deck DA.

The first deck DA may include a plurality of first conductive patterns 200, a plurality of second conductive patterns 240, and a plurality of first memory cells MCA. The first deck DA may further include a first lower electrode 210A disposed between a first memory cell MCA and a first conductive pattern 200, and a first upper electrode 230A disposed between the first memory cell MCA and a second conductive pattern 240.

The plurality of first conductive patterns 200, the plurality of second conductive patterns 240, the plurality of first memory cells MCA, the first lower electrodes 210A, and the first upper electrodes 230A may be arranged in the same structure as the plurality of first conductive patterns 200, the plurality of second conductive patterns 240, the plurality of memory cells MC, the lower electrodes 210, and the upper electrodes 230, which are shown in FIG. 2A.

The second deck DB may include the plurality of second conductive patterns 240, a plurality of third conductive patterns 260, and a plurality of second memory cells MCB. The plurality of second conductive patterns 240 may be shared by the first deck DA and the second deck DB.

The plurality of third conductive patterns 260 may be arranged above the plurality of second conductive patterns 240 in the third direction D3, and extend in the first direction D1 intersecting the plurality of second conductive patterns 240.

Each of the second memory cells MCB may be disposed in an area in which a second conductive pattern 240 and a third conductive pattern 260 intersect each other, and be disposed between the second conductive pattern 240 and the third conductive pattern 260.

The second deck DB may further include a second lower electrode 230B disposed between the second memory cell MCB and the second conductive pattern 240, and a second upper electrode 210B disposed between the second memory cell MCB and the third conductive pattern 260. A voltage applied to the second conductive pattern 240 may be applied to the second memory cell MCB through the second lower electrode 230B. A voltage applied to the third conductive pattern 260 may be applied to the second memory cell MCB through the second upper electrode 210B.

Two or more second memory cells MCB disposed in a line in the second direction D2 may be connected in parallel to each of the second conductive patterns 240. Two or more second memory cells MCB disposed in a line in the first direction D1 may be connected in parallel to each of the third conductive patterns 260.

The plurality of first conductive patterns 200 and the plurality of third conductive patterns 260 may be used as a plurality of word lines WL11 to WL13 and a plurality of word lines WL21 to WL23, respectively. The plurality of second conductive patterns 240 may be used as a plurality of bit lines BL1 to BL3.

The first memory cell MCA may include a first chalcogenide layer 220A, and the second memory cell MCB may include a second chalcogenide layer 220B.

Referring to FIG. 2C, a memory cell array may be implemented as a three-dimensional memory cell array. The three-dimensional memory cell array may include a plurality of first conductive patterns 200C, a plurality of second conductive patterns 240C intersecting the plurality of first conductive patterns 200C, and a chalcogenide layer 220C formed at intersections of the plurality of first conductive patterns 200C and the plurality of second conductive patterns 240C.

Each of the first conductive patterns 200C may have a flat plate shape extending in the first direction D1 and the second direction D2. The plurality of first conductive patterns 200C may be stacked to be spaced apart from each other in the third direction D3. The plurality of first conductive patterns 200C may be used as a plurality of word lines WL1 to WL3.

Each of the plurality of second conductive patterns 240C may extend in the third direction D3 to penetrate the plurality of first conductive patterns 200C. Although not shown in the drawing, a plurality of bit lines respectively connected to the plurality of second conductive patterns 240C may be disposed above the plurality of second conductive patterns 240C to extend in the first direction D1 or the second direction D2. The chalcogenide layer 220C may surround a sidewall of a second conductive pattern 240C corresponding thereto. Some portions of the chalcogenide layer 220C, disposed at intersections of the plurality of first conductive patterns 200C and the second conductive pattern 240 corresponding to the chalcogenide layer 220C, may be used as memory cells.

Each of the chalcogenide layers 220, 220A, 220B, and 220C shown in FIGS. 2A to 2C may have a compositional gradient corresponding to a program state (e.g., the set state or the reset state) of a corresponding memory cell as described with reference to FIG. 1. The magnitude of a threshold voltage corresponding to the program state of the memory cell may be changed by controlling the compositional gradient of each of the chalcogenide layers 220, 220A, 220B, and 220C according to the program pulse. The compositional gradient of each of the chalcogenide layers 220, 220A, 220B, and 220C according to the program pulse may be changed according to one or more of a size of the memory cell, an electrode material, a magnitude of the program pulse, a width of the program pulse, and the like.

In the embodiments of the present disclosure, a window margin corresponding to a difference between the threshold voltage of the set state and the threshold voltage of the reset state is controlled to become 1V or higher, so that a read margin may be secured. In the embodiments of the present disclosure, in order to secure the read margin, the compositional gradient in the chalcogenide layer may be induced by the program pulse having the first polarity or the program pulse having the second polarity such that a content of at least one component of the chalcogenide layer has a difference of 5 at % or more between both ends of the memory cell.

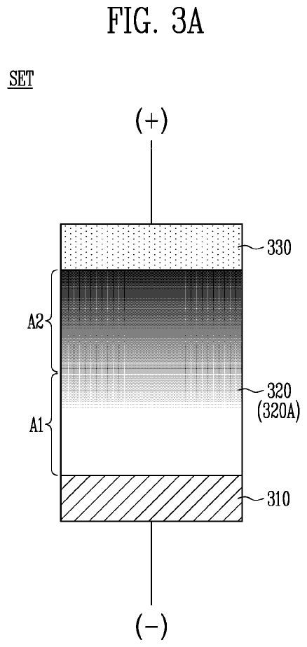

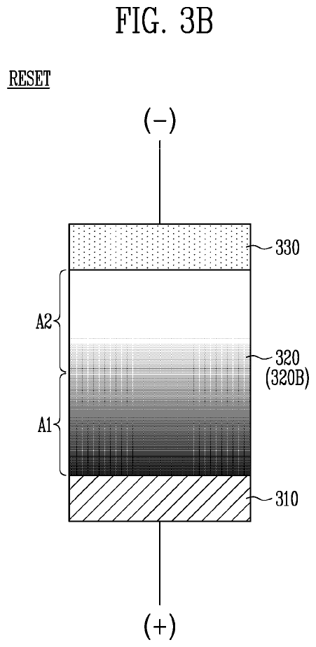

FIGS. 3A and 3B illustrate a compositional gradient of a chalcogenide layer in accordance with an embodiment of the present disclosure. FIG. 3A illustrates a compositional gradient inside the chalcogenide layer in the set state, and FIG. 3B illustrates a compositional gradient inside the chalcogenide layer in the reset state.

Referring to FIGS. 3A and 3B, a chalcogenide layer 320 may be included in a memory cell as described with reference to FIGS. 1 and 2A to 2C. The chalcogenide layer 320 may be interposed between a first electrode 310 and a second electrode 330. Each of the lower electrode 210 shown in FIG. 2A, the first lower electrode 210A shown in FIG. 2B, the second upper electrode 210B shown in FIG. 2B, and the first conductive pattern 200C shown in FIG. 2C may correspond to the first electrode 310. Each of the upper electrode 230 shown in FIG. 2A, the first upper electrode 230A shown in FIG. 2B, the lower electrode 230B shown in FIG. 2B, and the second conductive pattern 240C shown in FIG. 2C may correspond to the second electrode 330.

The chalcogenide layer 320 may be divided into a first area A1 adjacent to the first electrode 310 and a second area A2 adjacent to the second electrode 330. As described with reference to FIGS. 1 and 2A to 2C, a content of at least one component inside the chalcogenide layer 320 may have a difference of 5 at % or more between both ends of the memory cell due to a program pulse applied to the memory cell. That is, the content of at least one component inside the chalcogenide layer 320 may have a difference of 5 at % or more between the first area A1 and the second area A2 due to the program pulse.

In an embodiment, the chalcogenide layer 320 may be configured as a compound of elements in Group 14, Group 15, and Group 16. The elements in Group 14, Group 15, and Group 16 are referred to as a Group 14 element, a Group 15 element, and a Group 16 element, respectively. The Group 14 element may include at least one of germanium (Ge) and silicon (Si), the Group 15 element may include at least one of arsenic (As) and antimony (Sb), and the Group 16 element may include at least one of selenium (Se), sulfur (S), and tellurium (Te). In an embodiment, the chalcogenide layer 320 may be configured as a compound of germanium (Ge), arsenic (As), and selenium (Se). In an embodiment, a dopant including one or more of boron (B), carbon (C), nitrogen (N), aluminum (Al), silicon (Si), phosphor (P), manganese (Mn), nickel (Ni), gallium (Ga), indium (In), silver (Ag), tin (Sn), antimony (Sb), tungsten (W), and the like may be added in the chalcogenide layer 320.

The Group 15 element and the Group 16 element included in the chalcogenide layer 320 may move in directions opposite to each other in response to the program pulse, so that a compositional gradient is formed inside the chalcogenide layer 320. In order to secure a read margin, the compositional gradient may be induced such that a content of at least one of the Group 15 element and the Group 16 element in the chalcogenide layer 320 has a difference of 5 at % or more between the first area A1 and the second area A2. The Group 14 element may be induced by the program pulse to have a content of 15 at % to 30 at % in each of the first area A1 and the second area A2.

Referring to FIG. 3A, a chalcogenide layer 320A may have a first compositional gradient corresponding to the set state due to a program pulse having a first polarity. The program pulse having the first polarity may have a positive polarity. When the program pulse has the first polarity, a first voltage may be applied to the first electrode 310, and a second voltage higher than the first voltage may be applied to the second electrode 330. By the program pulse having the first polarity, the Group 15 element may move to the first electrode 310, and the Group 16 element may move to the second electrode 330. Accordingly, the content of the Group 16 element may become higher in the second area A2 than in the first area A1, and the content of the Group 15 element may become higher in the first area A1 than in the second area A2.

Referring to FIG. 3B, a chalcogenide layer 320B may have a second compositional gradient corresponding to the reset state due to a program pulse having a second polarity. The program pulse having the second polarity may have a negative polarity. When the program pulse has the second polarity, a third voltage may be applied to the first electrode 310, and a fourth voltage lower than the third voltage may be applied to the second electrode 330. By the program pulse having the second polarity, the Group 15 element may move to the second electrode 330, and the Group 16 element may move to the first electrode 310. Accordingly, the content of the Group 15 element may become higher in the second area A2 than in the first area A1, and the content of the Group 16 element may become higher in the first area A1 than in the second area A2.

As described in FIGS. 3A and 3B, differences between the content of the Group 15 element and the content of the Group 16 element occur in the first area A1 and the second area A2 of the memory cell due to the program pulse, and a compositional gradient may be formed inside the chalcogenide layer 320. The compositional gradient formed inside the chalcogenide layer 320 may vary according to the polarity of the program pulse. The compositional gradient changing according to the polarity of the program pulse may have a threshold voltage corresponding thereto.

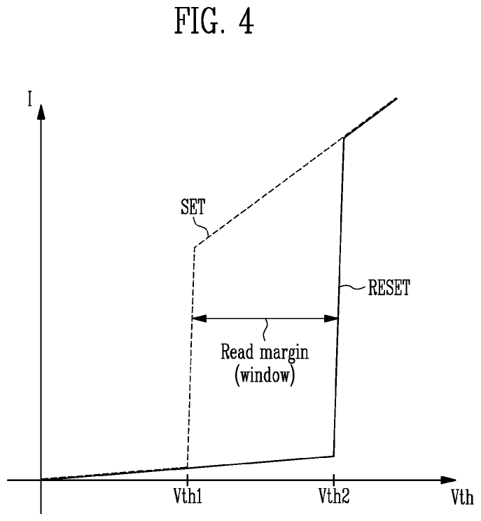

FIG. 4 is a graph illustrating a current-voltage characteristic according to a program state of a memory cell in accordance with an embodiment of the present disclosure.

Referring to FIG. 4, a memory cell in the set state may have a first threshold voltage Vth1 due to the first compositional gradient, and a memory cell in the reset state may have a second threshold voltage Vth2 due to the second compositional gradient.

In the embodiment of the present disclosure, as described with reference to FIGS. 3A and 3B, the content of at least one element in the chalcogenide layer 320 may have a difference of 5 at % or more between the first area A1 and the second area A2 so as to secure a read margin (window) having 1V or higher. Therefore, in an embodiment, a difference of contents of each of the Group 15 element and the Group 16 element in the first area A1 and the second area A2 may be 5 at % or more.

The above-described content difference may be induced by a polarity of a program pulse after a chalcogenide layer having a uniform composition ratio is formed in the chalcogenide layer. That is, when the chalcogenide layer has the uniform composition ratio, contents in the chalcogenide layer, e.g., contents of the Group 15 element and the Group 16 element, are substantially the same in a first area and a second area. However, embodiments are not limited thereto. In another embodiment, a first chalcogenide layer and a second chalcogenide layer, which have different composition ratios, are alternately stacked in a process of forming the chalcogenide layer, so that the above-described content difference can be pre-defined before the program pulse is applied to the memory cell. That is, elements included in the first chalcogenide layer and the second chalcogenide layer, e.g., the Group 15 element and the Group 16 element, have different composition ratios in the first chalcogenide layer and the second chalcogenide layer.

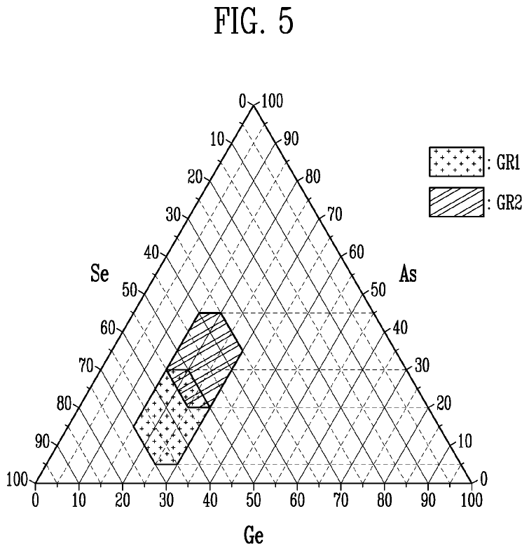

FIG. 5 is a phase equilibrium diagram illustrating a composition ratio of a chalcogenide layer of a memory cell in accordance with an embodiment of the present disclosure.

Referring to FIG. 5, the chalcogenide layer may include three components, e.g., germanium (Ge), arsenic (As), and selenium (Se).

When a program pulse is applied to the memory cell, the three components, i.e., germanium, arsenic, and selenium, may be contained in a composition range of a first group GR1 in an area to which a relatively high voltage (hereinafter, referred to as a “positive voltage” for convenience of description) is applied, and be contained in a composition range of a second group GR2 in an area to which a relatively low voltage (hereinafter, referred to as a “negative voltage” for convenience of description) is applied.

For example, germanium, arsenic, and selenium may be contained in the composition range of the first group GR1 in the second area A2 shown in FIG. 3A or in the first area A1 shown in FIG. 3B. Corresponding to this, germanium, arsenic, and selenium may be contained in the composition range of the second group GR2 in the first area A1 shown in FIG. 3A or in the second area A2 shown in FIG. 3B. The second voltage described with reference to FIG. 3A and the third voltage described with reference to FIG. 3B may correspond to the positive voltage, and the first voltage described with reference to FIG. 3A and the fourth voltage described with reference to FIG. 3B may correspond to the negative voltage. However, embodiments are not limited thereto. In another embodiment, the first voltage and the fourth voltage may correspond to a ground voltage.

Referring to the first group GR1 and the second group GR2, germanium may be induced to have 15 at % to 30 at % in each of areas to which the positive voltage and the negative voltage are applied as described with reference to FIGS. 3A and 3B.

Referring to the first group GR1, arsenic may be contained to have a content of 5 at % to 30 at % in the area (e.g., the second area A2 shown in FIG. 3A or the first area A1 shown in FIG. 3B) to which the positive voltage is applied. Selenium may be contained to have a content of 50 at % to 70 at % in the area (e.g., the second area A2 shown in FIG. 3A or the first area A1 shown in FIG. 3B) to which the positive voltage is applied.

Referring to the second group GR2, arsenic may be contained to have a content of 20 at % to 45 at % in the area (e.g., the first area A1 shown in FIG. 3A or the second area A2 shown in FIG. 3B) to which the negative voltage is applied. Selenium may be contained to have a content of 35 at % to 55 at % in the area (e.g., the first area A1 shown in FIG. 3A or the second area A2 shown in FIG. 3B) to which the negative voltage is applied.

Referring to the first group GR1 and the second group GR2, the content of each of selenium and arsenic may have a difference of 5 at % or more in the area to which the negative voltage is applied and the area to which the positive voltage is applied according to the polarity of the program pulse. In the area to which the positive voltage is applied, germanium, arsenic, and selenium are controlled to be contained in the composition range of the first group GR1. In the area to which the negative voltage is applied, germanium, arsenic, and selenium are controlled to be contained in the composition range of the second group GR2. Accordingly, a read margin may be secured.

In accordance with the present disclosure, the compositional gradient inside the chalcogenide is controlled, so that a threshold voltage difference according to the polarity of the program pulse may be increased. Accordingly, a read margin may be secured, and thus the operational reliability of the semiconductor memory device including the chalcogenide may be improved.

What is claimed is:

1. A semiconductor memory device, comprising:
a memory cell interposed between a first electrode and a second electrode, and configured with a chalcogenide layer that includes three or more components; and
a peripheral circuit configured to provide a program pulse to the memory cell,
wherein the program pulse induces a compositional gradient in the chalcogenide layer such that a content of at least one component of the chalcogenide layer has a difference of 5 at % or more between a first area and a second area in the chalcogenide layer, the first area being adjacent to the first electrode, the second area being adjacent to the second electrode.

2. The semiconductor memory device of claim 1, wherein the chalcogenide layer includes a Group 14 element, a Group 15 element, and a Group 16 element.

3. The semiconductor memory device of claim 2, wherein the Group 14 element includes at least one of germanium (Ge) and silicon (Si),
wherein the Group 15 element includes at least one of arsenic (As) and antimony (Sb), and
wherein the Group 16 element includes at least one of selenium (Se), sulfur (S), and tellurium (Te).

4. The semiconductor memory device of claim 3, wherein the chalcogenide layer further includes a dopant of at least one of boron (B), carbon (C), nitrogen (N), aluminum (Al), silicon (Si), phosphor (P), manganese (Mn), nickel (Ni), gallium (Ga), indium (In), silver (Ag), tin (Sn), antimony (Sb), and tungsten (W).

5. The semiconductor memory device of claim 2, wherein the program pulse induces a content of at least one of the Group 15 element and the Group 16 element in the chalcogenide layer to have a difference of 5 at % or more between the first area and the second area.

6. The semiconductor memory device of claim 2, wherein the program pulse induces a content of the Group 14 element to be 15 at % to 30 at % in each of the first area and the second area.

7. The semiconductor memory device of claim 1, wherein the chalcogenide layer includes germanium (Ge), arsenic (As), and selenium (Se).

8. The semiconductor memory device of claim 7, wherein the program pulse induces a content of arsenic in the chalcogenide layer to have a difference of 5 at % or more between the first area and the second area.

9. The semiconductor memory device of claim 7, wherein the program pulse induces a content of selenium in the chalcogenide layer to have a difference of 5 at % or more between the first area and the second area.

10. The semiconductor memory device of claim 7, wherein the program pulse induces a content of germanium to be 15 at % to 30 at % in each of the first area and the second area.

11. The semiconductor memory device of claim 7, wherein, when the program pulse has a first polarity, a first voltage is applied to the first electrode and a second voltage higher than the first voltage is applied to the second electrode such that germanium and arsenic move to the first electrode and selenium moves to the second electrode.

12. The semiconductor memory device of claim 11, wherein, when the program pulse has a second polarity different from the first polarity, a third voltage is applied to the first electrode and a fourth voltage lower than the third voltage is applied to the second electrode such that germanium and arsenic move to the second electrode and selenium moves to the first electrode.

13. The semiconductor memory device of claim 7, wherein, when the program pulse has a first polarity, a first voltage is applied to the first electrode and a second voltage higher than the first voltage is applied to the second electrode such that arsenic is contained in the first area to have a content of 20 at % to 45 at % and is contained in the second area to have a content of 5 at % to 30 at %.

14. The semiconductor memory device of claim 13, wherein, when the program pulse has a second polarity different from the first polarity, a third voltage is applied to the first electrode and a fourth voltage lower than the third voltage is applied to the second electrode such that arsenic is contained in the first area to have a content of 5 at % to 30 at % and is contained in the second area to have a content of 20 at % to 45 at %.

15. The semiconductor memory device of claim 7, wherein, when the program pulse has a first polarity, a first voltage is applied to the first electrode and a second voltage higher than the first voltage is applied to the second electrode such that selenium is contained in the first area to have a content of 35 at % to 55 at % and is contained in the second area to have a content of 50 at % to 70 at %.

16. The semiconductor memory device of claim 15, wherein, when the program pulse has a second polarity different from the first polarity, a third voltage is applied to the first electrode and a fourth voltage lower than the third voltage is applied to the second electrode such that selenium is contained in the first area to have a content of 50 at % to 70 at % and is contained in the second area to have a content of 35 at % to 55 at %.
